(19) United States
(12) Patent Application Publication
(10) Pub. No.: US 2015/0079523 A1
(43) Pub. Date: Mar. 19, 2015

(54) POLYMER SHEET PATTERNING AND ITS ASSEMBLY USING SLIT CHANNEL LITHOGRAPHY

(71) Applicants: Minggan LI, Oakville (CA); Dae Kun HWANG, Toronto (CA); Janusz KOZINSKI, Toronto (CA)

(72) Inventors: Minggan LI, Oakville (CA); Dae Kun HWANG, Toronto (CA); Janusz KOZINSKI, Toronto (CA)

(21) Appl. No.: 14/484,950

(22) Filed: Sep. 12, 2014

Related U.S. Application Data
(60) Provisional application No. 61/877,496, filed on Sep. 13, 2013.

(51) Int. Cl. G03F 7/20

(52) U.S. Cl. CPC G03F 7/2002
USPC 430/319; 430/322; 430/311; 355/53

(57) ABSTRACT

Synthesizing polymeric sheets in a slit fluidic channel by projection of a pulse of illumination to the channel. A slit channel can include a polymeric device with a plane's width larger than 1 mm. A glass plate is placed above the channel to prevent the channel from sagging. A photocurable prepolymer is flowed through the channel. The flow is paused and an illumination is projected to the channel through a photomask, produces a polymer sheet. The polymer sheet is then flushed out by resuming the flow. This process is repeated enabling continuous synthesis of polymeric sheets. The sheets can obtain any patterns defined by the photomask design, such as micropores and other geometrical patterns. These polymer sheets can be used in many emerging areas of technologies such as lab-on-a-chip, tissue engineering and organic electronics.

### CROSS-REFERENCE TO RELATED APPLICATIONS

This application claims the benefit of priority to U.S. Provisional Patent Application Ser. No. 61/877,496 filed Sep. 13, 2013 entitled POLYMER SHEET PATTERNING AND ITS ASSEMBLY USING SLIT CHANNEL LITHOGRAPHY, the contents of which are hereby incorporated by reference into the Detailed Description of Example Embodiments.

### FIELD

Examples relate to techniques for synthesizing thin polymeric sheets in a slit fluidic channel.

### SUMMARY

Synthesizing thin polymeric sheets in a slit fluidic channel by projection of a pulse of illumination to the channel. A slit channel can be considered a polymeric device with plane's width larger than, for example, 1 mm. A solid layer is placed above the channel to prevent the channel from sagging. A photocurable prepolymer is flowed through the channel. The flow is paused and an illumination is projected to the channel through a photomask, produces a polymer sheet. The polymer sheet is then flushed out by resuming the flow. This process is repeated enabling continuous synthesis of polymeric sheets. The sheets can obtain any patterns defined by the photomask design, such as micropores and other geometrical patterns. In the sheet thickness direction, the pattern profile can be cylindrical or conical by adjusting the focal plane to different vertical positions of the channel. The surface of the sheets can be controlled to produce smooth, porous or wrinkled texture by changing the components and their concentrations in the prepolymer solution. These polymer sheets can be used in many emerging areas of technologies such as lab-on-a-chip, tissue engineering and organic electronics.

This technique can also be used for sheet assembly. First example is magnetic assembly. In the slit channel, at least one stream in the multistream system is mixed with magnetic particles. Projection of illumination produces a polymer sheet with a magnetic strip. Multiple polymer sheets with magnetic strips can be assembled by applying a magnetic field. In this way, the patterns on each sheet can be aligned in the vertical direction as desired.

Another example is for electronic packaging. An electrical microchip is focused in the middle of the slit channel by two sheath flows and stopped at certain location along the channel length. Subsequent project of illumination on to the channel produces an electrical circuit of a shape defined by the photomask simultaneously connecting the microchip bumps to the circuit. For instance, connecting a Radio Frequency Identification (RFID) chip to an antenna makes a RFID tag.

By taking advantage of the micropatterning ability of photolithography, laminar co-flow property and flow focusing feature of microfluidic channels, the present invention may be used to not only pattern functional polymer sheets bearing geometrical and chemical anisotropy but also assemble multiple hydrogel sheets into 3D structures and perform single-step attachment of RFID dies onto a patterned antenna for RFID tag fabrication. The continuous processing capacity of SFL allows this technique to operate at a high throughput fashion, which significantly simplifies polymer sheet synthesis and assembly processes while improving its efficiency.

In accordance with an example embodiment, there is provided a method for synthesizing polymeric sheets, including: providing a slit channel having a plane's width of at least 1 mm, providing a solid layer at the channel to prevent the channel from sagging, flowing a curable prepolymer through the channel, pausing the flow of curable prepolymer responsive to illumination, and projecting a source pulse of illumination to the channel through a photomask to the paused flow of curable prepolymer to produce a polymeric sheet.

In accordance with an example embodiment, there is provided a method for synthesizing polymeric sheets, including: providing a slit channel having an aspect ratio of width to height of at least 100:1, providing a solid layer at the channel to prevent the channel from sagging, flowing a curable prepolymer through the channel, pausing the flow of curable prepolymer responsive to illumination, and projecting a source pulse of illumination to the channel through a photomask to the paused flow of curable prepolymer to produce a polymeric sheet.

In accordance with an example embodiment, there is provided a method for synthesizing thin polymeric sheets, including: providing a slit channel having an aspect ratio of width to height of at least 100:1 and a plane's width of at least 1 mm, providing a solid layer at the channel to prevent the channel from sagging, flowing a curable prepolymer through the channel, pausing the flow of curable prepolymer responsive to illumination, and projecting a source pulse of illumination to the channel through a photomask to the paused flow of curable prepolymer to produce a polymeric sheet.

In accordance with an example embodiment, there is provided a method for synthesizing polymeric designs on a substrate film, including: providing a slit channel having a plane's width of at least 1 mm; providing a solid layer at the channel to prevent the channel from sagging, introducing a substrate film into the channel, flowing a curable prepolymer responsive to illumination through the channel, pausing the flow of curable prepolymer responsive to illumination, and projecting a source pulse of illumination to the channel through a photomask and through the substrate film to the paused flow of curable prepolymer responsive to illumination, to synthesize the polymeric designs onto the substrate film, and removing the substrate film having the polymeric designs thereon from the channel.

In accordance with an example embodiment, there is provided a method for synthesizing polymeric designs on a substrate film, including: providing a slit channel having a plane's width of at least 1 mm, providing a solid layer at the channel to prevent the channel from sagging, introducing a substrate film into the channel, flowing a curable prepolymer responsive to illumination through the channel, pausing the flow of curable prepolymer responsive to illumination, and projecting a source pulse of illumination to the channel through a photomask and through the substrate film to the paused flow of curable prepolymer responsive to illumination to produce the polymeric designs onto the substrate film; and removing the substrate film having the polymeric designs thereon from the channel.

In accordance with an example embodiment, there is provided a method for synthesizing polymeric sheets including membranes, including: providing a slit channel, providing a solid layer at the channel to prevent the channel from sagging, flowing a curable prepolymer responsive to illumination through the channel, pausing the flow of curable prepolymer responsive to illumination, and projecting a source pulse of illumination to the channel through a photomask to the paused flow of curable prepolymer responsive to illumination to produce a polymeric sheet including membranes.

In accordance with an example embodiment, there is provided a method for synthesizing a radio frequency identification tag, providing a slit channel, providing a solid layer at the channel to prevent the channel from sagging, flowing an electrically conductive curable prepolymer through the channel, carrying a die using the curable prepolymer responsive to illumination through the channel, pausing the flow of the electrically conductive curable prepolymer responsive to illumination when the die is aligned with the photomask designed in an antenna pattern, and projecting a source pulse of illumination to the channel through the photomask to the paused flow of the electrically conductive curable prepolymer to form an antenna and to bond the die to the antenna, to produce a radio frequency identification tag.

In accordance with an example embodiment, there is provided a method for synthesizing polymeric sheets, including: providing a slit channel having an aspect ratio of width to height of at least 100:1, providing a solid layer at the channel to prevent the channel from sagging, flowing a curable prepolymer responsive to illumination through the channel, pausing the flow of the curable prepolymer responsive to illumination, and projecting a source pulse of illumination to the channel through a photomask to the paused flow of the curable prepolymer responsive to illumination, to product a polymeric sheet.

In accordance with an example embodiment, there is provided a system for synthesizing thin polymeric sheets, including: a slit channel having a plane's width of at least 1 mm, a solid layer at the channel to prevent the channel from sagging, a control for controlling flow of a curable prepolymer to be flowing or paused, the curable prepolymer responsive to illumination, a photomask; and a source pulse of illumination to the slit channel projected to the channel through the photomask to the paused flow of curable prepolymer, to produce a polymer sheet.

### BRIEF DESCRIPTION OF THE DRAWINGS

Reference will now be made, by way of example, to the accompanying drawings which show example embodiments of the present application, and in which:

FIG. 1 illustrates: Polymer sheet synthesis in a slit microfluidic channel with a high aspect ratio using flow lithography. a). Schematic illustration of polymer sheet patterning. The PDMS channel is strengthened by a glass plate to avoid sagging of the channel. A prepolymer solution in the channel is selectively polymerized by UV light through a photomask. Sheets with desirable patterns can be readily produced by changing the photomask. b) Differential interference contrast (DIC) image of a PEG-DA sheet with an ordered pore array. Inset is a SEM image of the sheet. c) Bright field image of an elongated sheet produced by polymerizing several single sheets with overlapped edges. The sheet is then pulled out and can be rolled on a rod. Scale bars 400 μm (b), 200 μm (b inset) and 1 mm (c).

FIG. 2 illustrates: Versatile functional sheet synthesis. a) Bright field image of a Pacman-arena styled sheet, b) Fluorescence image of a fingerprint patterned sheet, and c) DIC image of a sheet with a pore size gradient ranging from 10 to 300 μm. d) Illustration of cylindrical and cone shape micropores fabrication process. Cylindrical pores are obtained by focusing a photomask in the middle of the channel depth while cone shape pores are formed by lowering the focal plane. e) and f) are the SEM images of the cylindrical and cone shape pores in the sheets respectively. g-i) are the SEM image of sheets with different surface morphologies. These sheets are made by changing the concentrations of ethanol in PEG-DA. g) 100% PEG-DA 575 and i) 60% ethanol, 35% PEG-DA 575. Both are with 5% Darcure 1173. h) 60% ethanol, 39% PEG-DA 200 and 1% Darcure 1173. Scale bars 1 mm (a-c), 40 μm (e, f), 2 μm (g, h) and 5 μm (i).

FIG. 3 illustrates: Cell encapsulated tissue sheet and the assembly of 3D tissue scaffolds. a) Illustration of synthesis of tissue sheet with patterned cell layers. Two side streams are PEG-DA water solution and the middle stream is PEG-DA solution in PBS with NIH 3T3 cells. b) Bright field image of a cell-laden sheet. Two sides of the sheet are PEG-DA hydrogel layers and the middle layer is the encapsulated cells. c) Fluorescence image of the tissue sheet in b) for the cell viability expressed by calcein AM (live cells, green) and ethidium homodimer (dead cells, red). d) Schematic of tubular hydrogel scaffold formation by rolling an elongated hydrogel sheet on a glass rod. After one piece of hydrogel is formed by UV exposure, the projection area is moved upstream so that the next piece of hydrogel can be formed with their edges connected. e) A fluorescence image of the tubular hydrogel scaffold. f) A fluorescence image of double-stream elongated sheets rolled around a metal tube at a certain angle for forming a long hydrogel tube. g) Illustration of hydrogel sheet formation with magnetic particles in the outer layers. Two side streams are PEG-DA water solution with 10% magnetic suspension and the middle streams are PEG-DA water solution. After making three of these magnetic hydrogel sheets, they are assembled in a PDMS reservoir at a right-angled corner by using a magnetic field (h). Inset is the three sheets before assembly. i) The pores are aligned in the vertical direction. Scale bars 500 μm (b, c), 1 mm (e, h), 400 μm (f) and 100 μm (i).

FIG. 4 illustrates: Single step fabrication of RFID tags. a) Schematic illustration of the flow lithography fabrication process. After focusing RFID microchips in the middle of the channel by two sheath flows, the flow is stopped. Then UV is exposed to the channel through an antenna-shaped photomask to polymerize the CNT prepolymer solution, simultaneously bonding the two bumps to the antenna. b) Microchip focusing and bonding process. Left is a bright field image of a microchip entering the sheath flow. Right is a DIC image of a polymerized antenna connected to the RFID chip. c) Bright field image of the fabricated RFID tag. d) Photographs of top and bottom views of the microchip bonding area. e) Photograph of the RFID tag inlay. After cleaning the bonded RFID tag, it is immersed in PEG-DA prepolymer solution and encapsulated inside by polymerizing prepolymer solution. Scale bars 1 mm (b, c) and 500 μm (d).

FIG. 5 illustrates: Photographs of RFID die attached to different patterned antenna. Scale bar 1 mm.

FIG. 6 illustrates: Schematic of the lubrication layer in the PDMS channel.

FIG. 7 illustrates: Photographs of polymer sheets with smooth surface a) porous surface b) and wrinkled surface c) Scale bar 1 mm.

FIG. 8 illustrates: A double stream elongated hydrogel sheet. Scale bar 1 mm.

FIG. 9 illustrates: Schematic of pull out lithography.

FIG. 10 illustrates: Schematic of a patterned circuit for sensing.

Similar reference numerals may have been used in different figures to denote similar components.

### DESCRIPTION OF EXAMPLE EMBODIMENTS

Patterned polymer sheets are widely used in a broad range of industries, and sheets with different patterned properties play different functional roles in their applications, such as porous sheets for filtrations, electrically conductive sheets for organic electronics, [1] surface textured sheet for particles immobilization, condensation of proteins, and smart adhesives, [2-4] and hydrogel sheets for tissue engineering and stem cell differentiation control. [5] Recently, advanced applications of patterned polymer sheets have been increasingly explored in emerging lab-on-a-chip technologies, in which they serve for multifraction separation, [6] gas sensing, [7] cell trapping and analysis, [8] bioassay, [9] and bioreactors. [10] Aside from single layer sheets, which usually work as a functional component in a system, assembled sheets may be much more useful and can expand its role to work as an independent functional system. For example, assembling microchannel patterned cell-laden hydrogel sheets into 3D structures vascularizes 3D artificial tissues [11] and attaching a radio-frequency-identification (RFID) microchip to a patterned organic electrical circuit essentially forms an RFID tag used for remote communication. [12]

There are numerous methods for patterning polymer sheets, including scanning beam lithography, [13] photolithography, [14] and soft and hard mold lithography. [15] Scanning beam lithography uses a laser, electron, or ion beam to scan a selected area to form a patterned polymer sheet. This technique can generate high-resolution features with arbitrary patterns, but it is time-consuming and expensive. Photolithography is a parallel process that can create patterned polymer sheets by a one-time UV light exposure through a designed photomask onto a photoresist material. However, it is a low throughput method owing to its batch-process nature. In addition, photoresist materials commonly used in photolithography are not ideal for biomedical applications where the biocompatibility or functionalization of the sheet is critical. Soft and hard mold lithography can pattern a wide range of materials and its continuous fabrication techniques, such as embossing by “rolling molds” [16] and imprinting by step&stamp process can achieve a high throughput. [17] Mold-based lithography however, is still not a very cost-effective method for polymer sheet patterning since any change in the pattern design requires a new fabrication of the mold. Further, for all of the above-mentioned patterning methods, creating chemically anisotropic sheets needs cumbersome multi-step alignment and protection procedures, making it difficult to perform in a controllable and high-throughput fashion. More importantly, these methods fundamentally lack the ability for parts positioning and sheet assembly.

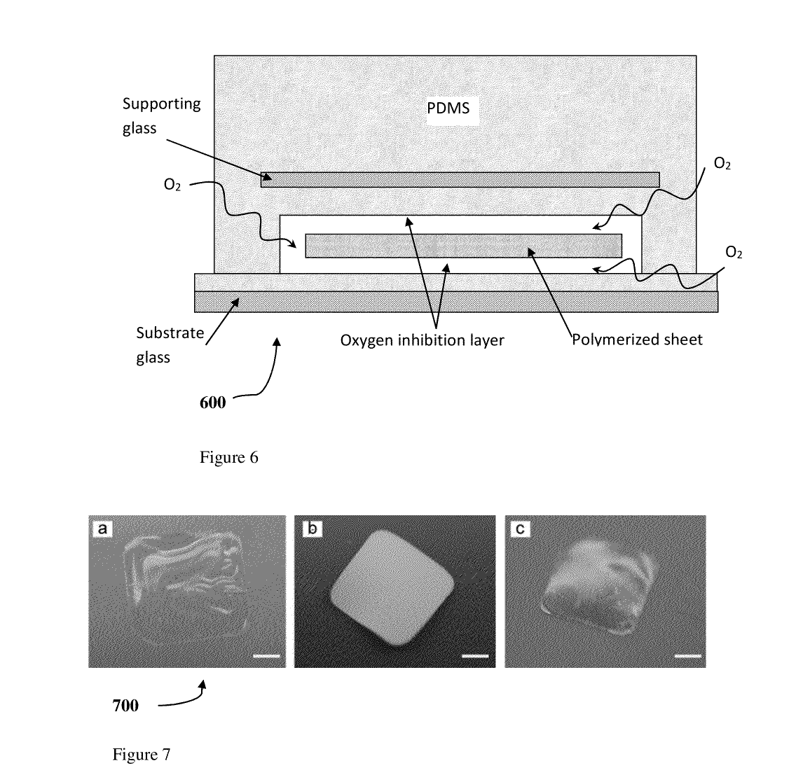

We introduce here a synthesis method for patterning polymer sheets based on stop flow lithography (SFL), which not only fabricates versatile patterned polymer sheets but also manufacture assembled sheet systems, both in a one step and high throughput fashion, overcoming many of the limitations of current techniques. SFL, which was intended for non-spherical microparticle synthesis, is a photolithographic method integrated in a microfluidic channel. In this technique, a photocurable prepolymer solution is flowed through a microfluidic channel and a UV light is projected to the channel through a photomask while the flow is stopped, synthesizing a microparticle with photomask defined shape. By taking advantage of the lubrication layer at the channel walls caused by oxygen inhibition (FIG. 6), [18] synthesized particles are flushed out immediately by resuming the flow. This process is repeated and microparticles are fabricated continuously. Due to its easy control over shape and chemical anisotropy in combination with its high throughput, this technique has been successfully applied for synthesis of various micro particles. [19-22]

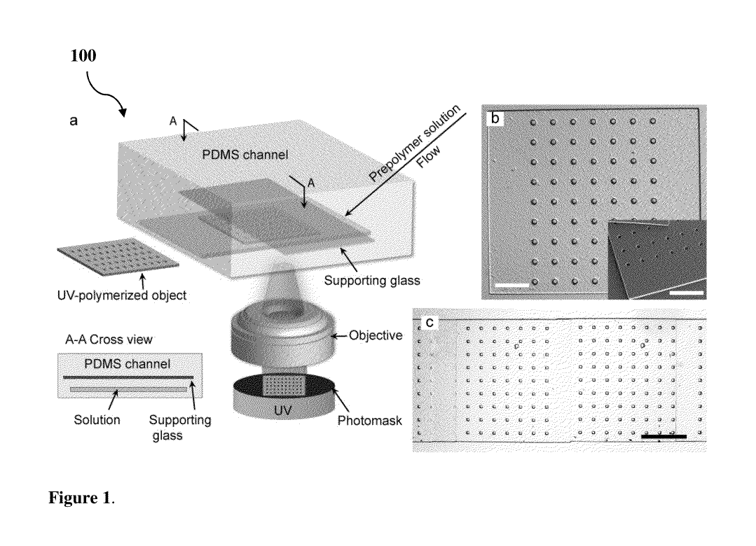

Despite of the product variety of these applications, Polydimethylsiloxane (PDMS) is mainly used for the channel material primarily for its optical transparency and oxygen diffusion capacity. However, due to the weak mechanical properties of PDMS, the channels are usually at most O(100) μm in width since wider channels may suffer from a sagging problem, limiting the channels to low aspect ratios (AR, ratio of channel width to height, usually less than 20) and thus limits its production to low aspect ratio micro-scale objects. By placing a glass plate into a PDMS channel, used to prevent channel deformation, we greatly widened the channel width (AR>100) and are able to fabricate high aspect ratio polymer sheets. As illustrated in FIG. 1, an example embodiment of the polymeric sheet synthesis and assembly system 100 is shown having a slit PDMS channel with a high aspect ratio is fabricated by placing a supporting glass plate just above the channel. A photocurable prepolymer solution is flowed through this channel and polymerized by projection of UV light through a photomask (FIG. 1.a). FIG. 1.b shows a 2.7 mm by 2.7 mm sheet with thickness 20 μm, made from poly (ethylene glycol) diacrylate (PEG-DA), and patterned with a 25 μm diameter pore matrix. Furthermore, by polymerizing each subsequent single sheet with overlapped edges, an elongated sheet of customizable length can be produced (FIG. 1.c).

By extending microfluidic channel dimensions, we greatly expand its application area, from current microparticle fabrication to near centimeter sheet synthesis and assembly. By taking advantage of arbitrary pattern transference and high resolution shape control intrinsic to photolithography, along with repeating process capacity, this technique can be used to readily synthesize polymer sheets with any pattern in a high throughput fashion. In addition, the laminar co-flow properties associated with microfluidics allow this technique to pattern sheets with tunable chemical anisotropy. Further, by using the fluid dynamics in a microfluidic channel, for instance particle focusing by sheath flows, this technique is able to position a micro-object in the channel and then in-situ connect it to a patterned sheet via a one step UV projection, conveniently constructing an assembled functional sheet systems in a simple slit channel. In this work, we demonstrate the versatile potential of this technique from single layer sheet patterning to multi-layer or multi-parts assembly, revealing its powerful processing ability as a tool for polymer sheet synthesis and assembly.

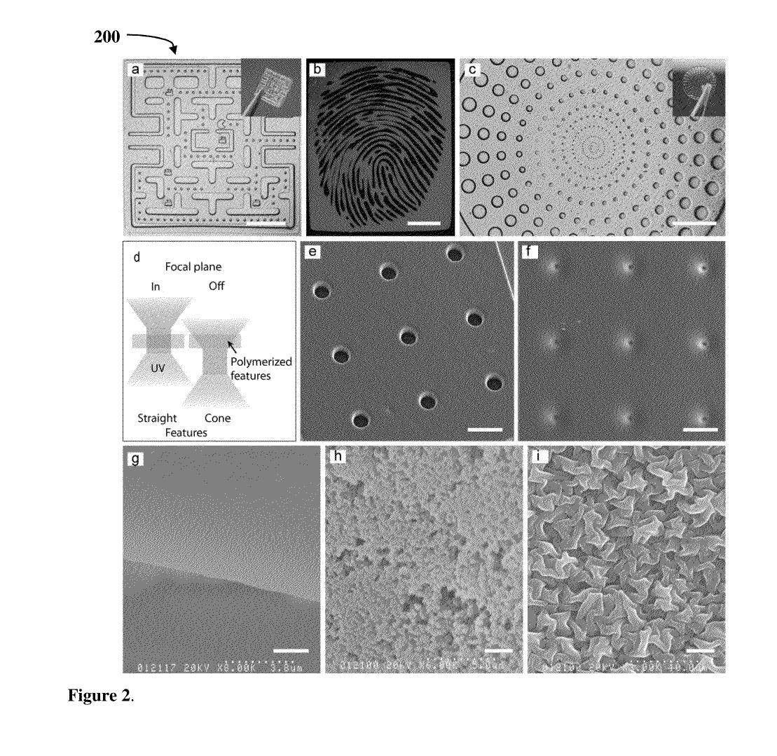

FIG. 2 shows various types of single layer PEG-DA sheets 200 synthesized by a single projection of UV light to the microfluidic channel through photomasks. FIG. 2a, b demonstrate the complex geometry patterning capacity of this technique by simply changing the photomasks. Up to 6 mm diameter sheets can be fabricated and down to 5 μm features can be obtained using our current experimental configuration. This high-resolution patterning and high-throughput processing ability has potential use in small size organic electronics. [23]

As shown in FIG. 2c, microscale pore gradients starting from 5 μm can be easily patterned on a polymer sheet, and patterned sheets with this feature are proven to be very useful in multiple fraction separation and filtration. [6] In addition, controllable pore profiles can be generated, from cylindrical to conical pores by simply adjusting the focal plane of UV projection, as demonstrated in FIG. 2d-f. The shape of UV light near the focal plane can be approximated to be straight in a small depth, as schematically shown in FIG. 2d. Placing the focal plane inside of the channel results in cylindrical pores (FIG. 2e), and conical pores (FIG. 2f) are obtained by aligning the focal plane with the cone profile region of the UV light inside the channel. Although cylindrical pores are widely used for cell trapping and analysis, conical pores are also beneficial since they enhance oxygen and medium delivery for cell culture, [24] and improve assay sensitivity for biochemical analysis. [25]

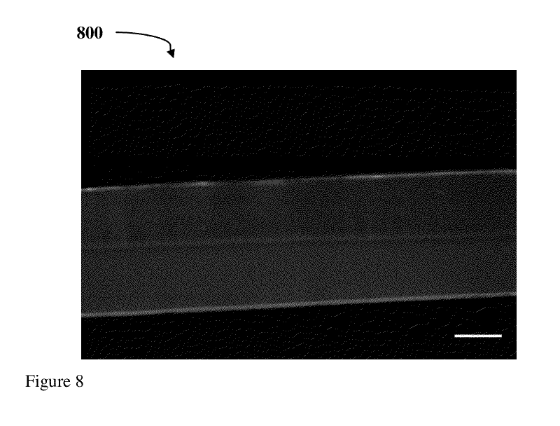

Controllable textures can be synthesized onto the sheet surface by tuning the composition of the prepolymer solution. As shown in FIG. 2g-i, solid, porous and wrinkled surface morphologies are obtained by only varying the ethanol concentration in the prepolymer solutions. Due to phase separation in the prepolymer solution during the polymerization process, porous sheets with pore sizes down to O(100) nm scale can be produced (FIG. 2h). These nanoporous sheets themselves can be used for nanofiltration, separation, and in combination with the microscale pore gradients may be effective for multiscale and multifraction filtration and separation. The winkled surface is generated by the swelling of the partially polymerized prepolymer thin layer between the uncured prepolymer at the channel wall and the constrained fully polymerized sheets in the middle of the channel. These wrinkled surfaces have various advanced applications such as in protein analysis, [4] thin film metrology, [26] responsive microfluidic channels, [27] and smart adhesives, [2] among others. It is noted that these surface textured sheets have different light transparency due to their different surface morphologies (FIG. 7).

In addition to the ability to pattern complex geometries in polymer sheets with controlled pore shape and surface morphology, by introducing multiple flow streams with different chemical properties in the slit channel, polymer sheets with anisotropic chemical properties can be synthesized. Its one step yet versatile patterning ability along with its continuous processing capacity, allowing high-throughput, makes it a powerful polymer sheet patterning tool.

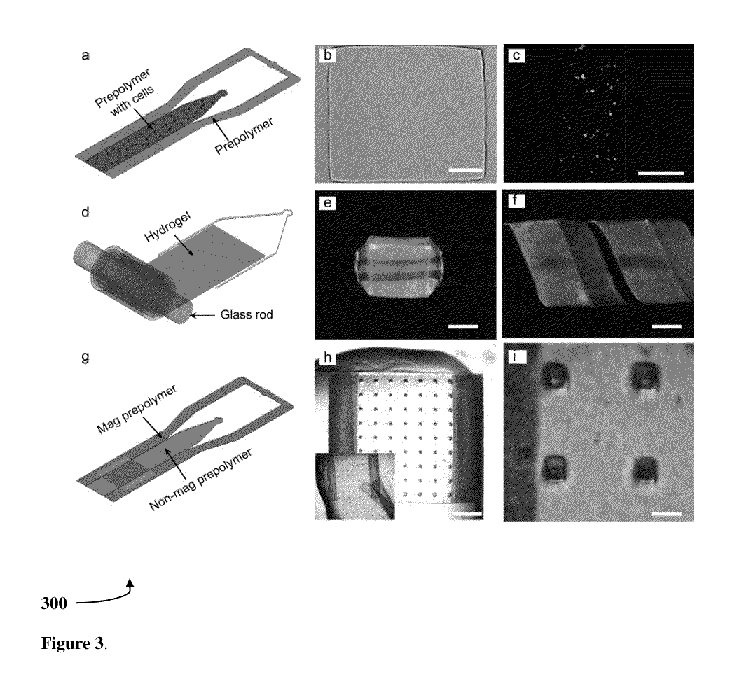

The hydrogel sheet patterning and cell encapsulation capability of this technique also make it a competent tool for making hydrogel scaffolds in tissue engineering applications. In tissue engineering, scaffolds play crucial roles in providing physical and chemical cues to promote cell attachment, guiding cell differentiation and assembling into 3D tissues or organs. [28] One of the strategies for 3D tissue scaffold construction is sheet-based tissue engineering, [29] in which hydrogel sheets with or without encapsulated cells are assembled into desired 3D structures for various tissue engineering applications, for example tubular artificial tissues by rolling up the sheets or 3D tissue regeneration by stacking up multiple layers of the sheets. By taking advantage of the hydrogel sheet patterning ability and laminar co-flow properties of microfluidics, this technique will be able to incorporate cell-laden hydrogel sheets with not only designed micropatterns for formation of interconnected microchannel networks after assembly, but also multiple cell types and tailored growth factor distributions for functional tissue regeneration. With its potential in tissue engineering, we have demonstrated, as shown in FIG. 3, the different sheet patterning strategies and 3D tissue scaffold assembly based on our technique.

FIG. 3a-c demonstrates single layer cell-laden sheet patterning 300. A three-stream slit channel was designed to show that different cells and growth factors can be incorporated into each of these streams (FIG. 3a). In our experiments, 3T3 fibroblasts were mixed with PEG-DA 700 water solution and flowed through the middle stream of the channel. The two side streams composed of PEG-DA 700 water solution without cells. At the downstream of the channel, these three streams were stopped and exposed to UV light through a rectangular photomask and simultaneously polymerized into a cell-laden hydrogel sheet (FIG. 3b), with dimensions of about 2.5 mm by 2.8 mm. The thickness of the resulting hydrogel sheets is about 50 μm and can be readily altered by changing the microfluidic channel height. By optimizing the process parameters such as PEG-DA and photoinitiator concentrations and UV exposure time, the maximum cell viability was retained. FIG. 3c shows the fluorescence image of the cell-laden hydrogel sheet, in which cells are stained by live/dead cell viability assay. Cell viability examination revealed that about 75% of cells remain alive after polymerization.

As previously mentioned elongated polymerized hydrogel sheets can be connected by overlapping edges of the subsequent sheet with the proceeding one (FIG. 3d). In this manner, it will be appreciated that as the preceding polymeric sheet (e.g. a first polymeric sheet) is formed and moved downstream, this preceding sheet will be understood to have a trailing edge. A subsequent polymeric sheet (e.g. a second polymeric sheet) is formed after illumination and this subsequent will be understood as having leading edge. The elongated sheet being formed from an overlap of the trailing and leading edges of these sheets. By rolling this long hydrogel sheet around a rod, a tubular structure can be obtained, for potential use in vascular or nerve conduit tissue engineering. In our experiments, a 2 mm diameter and 3 mm long hydrogel tube was obtained, as shown in FIG. 3e. Moreover, by using laminar co-flow, different chemical components can be incorporated into one sheet, which is useful in controlling cell and growth factor distributions in the scaffold. The sharp interface implies that multiple chemicals and cells types can be incorporated into one hydrogel sheet with controlled lateral distribution (FIG. 8). By rolling the sheet at a certain angle along a rod, a long tubular structure with chemical anisotropy can be obtained (FIG. 3f). This hydrogel patterning method can be readily adapted to produce different planar hydrogel materials.

A 3D scaffold was created by magnetic assembly of multiple layers of micropatterned hydrogel sheets, as seen in FIG. 3g-i. The magnetic property of the hydrogel sheet is generated by encapsulating magnetic microparticles at two sides of the hydrogel sheets. As demonstrated in FIG. 3g, the two side streams are flowed with magnetic microparticles mixed in PEG-DA water solution and the middle stream contains only PEG-DA water solution without magnetic particles. These magnetic hydrogel sheets with 5 mm side-length dimensions were collected in a rectangular water-filled PDMS reservoir for assembly (FIG. 3h). By applying a magnetic field, these sheets were dragged to the corner and aligned in the vertical direction of the reservoir (FIG. 3h), with the assistance of a slight agitation of the water. A magnified image in FIG. 3i shows the vertical alignment of these 60 μm square pores and formation of a through-hole 3D hydrogel structure, which is essential for nutrition supply and waste removal in large tissue regeneration. Creating hydrogel sheets with controlled cell and growth factor distributions in each individual sheet, and magnetically assembling those into 3D structures offers a unique route for the fabrication of 3D tissue scaffold with controlled spatial distribution of cells and growth factors.

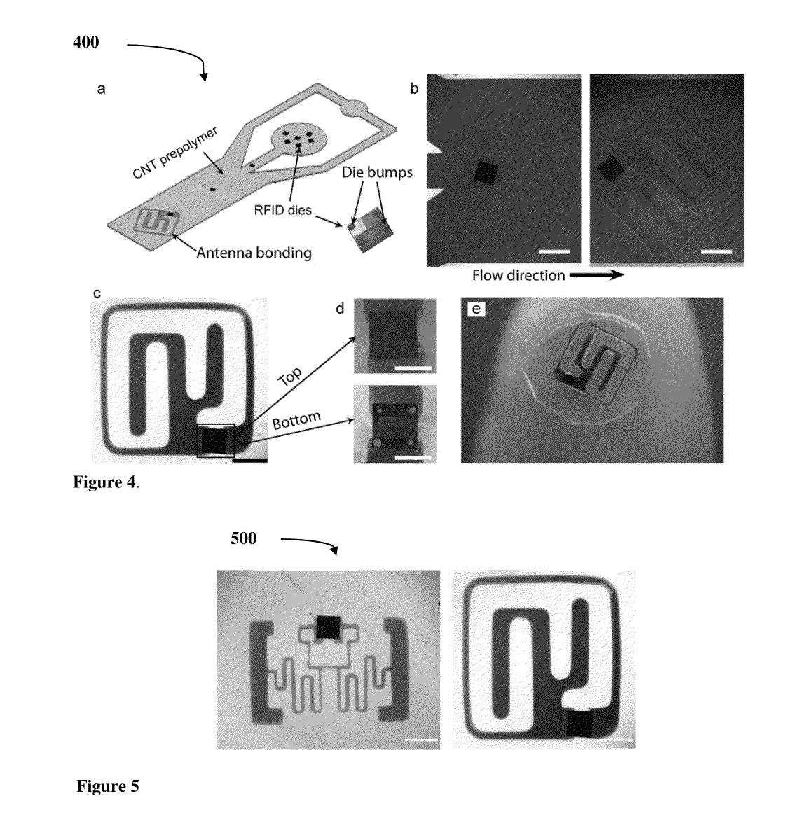

In addition to the aforementioned sheet patterning and their subsequent assembly, fluid dynamics in microfluidic channel, such as flow focusing for particle positioning, with integration of the patterning ability of our technique can greatly simplify and miniaturize many multi-step sheet assembly processes in industry. We demonstrated the compatibility of our technique with electronic packaging, particularly for radio frequency identification (RFID) tag fabrication, shown in FIG. 4.

In current RFID tags manufacturing, antennas are first fabricated through etching or screen printing and then fed into an assembly line for packaging through multi-step procedures, generally including antenna aligning, adhesive dispensing, pick-and-place die bonding, and adhesive curing. Due to the complex yet high precision antenna fabrication and die handling processes, the tag packaging contribute the most significant portion to the RFID tag manufacturing cost. [30] Although fluidic self assembly was proposed to replace the pick-and-place die positioning process, [31] it needs specifically shaped dies and corresponding shaped holes on the substrate in which the dies settle, resulting in extra manufacturing costs. In addition, the overloading of the number of the dies to increase the probability of matching and assembly requires unnecessary mass production of the dies.

By integrating the unique particle focusing feature of microfluidic channels and geometrical patterning ability of flow lithography, we are able to position micro-dies inside the channel, fabricate the antenna, and in situ attach the die to the antenna in a single step. Fabrication of RFID tags involves the attachment of bumps on the die (FIG. 4a) to a conductive antenna so that the energy collected by the antenna through the electromagnetic waves can power the die and allow the sending and receiving of information to and from a remote reader. As shown in FIG. 4a, the entire RFID tag fabrication is compacted into a slit microfluidic channel 400. In our case, carbon nanotubes (CNT) were used as conductors in the PEG-DA solution to make the polymerized antenna electrically conductive. The RFID die was placed in the middle inlet reservoir with the bumps facing down and focused in the middle of the channel by adjusting the flow rates of the two side streams. The die is stopped in the middle of the channel at a downstream location by stopping the flow. As the photomask is aligned with the die bumps, a UV light through an antenna-shaped photomask is projected on to the channel to polymerize the electrically conductive prepolymer solution into a designed antenna pattern while simultaneously connecting the bumps of the die to the two ends of the antenna (FIG. 4b, c). Attaching dies onto different antennas can be readily obtained by changing the photomasks with designed antenna patterns 500 (FIG. 5). The photograph of the bottom surface of the connected area confirms the binding between the bumps and antenna (FIG. 4d). The clear tracks of the bumps on the antenna surface remaining after forced removal of the die from the antenna imply that the bumps are firmly attached to the antenna. The tag inlay is made by encapsulating the tag into PEG-DA polymer by a second polymerization and is strong enough for operation (FIG. 4e). Known methods of boosting the conductivity of the antenna beyond, for example, ˜0.5 S/m to electrically function the die are contemplated. For example, efficient CNT loading and processing, [32] using silver nanowires as conductive filler [33] or in situ polymerization of composite polymers, [34] may be readily employed by those skilled in the art.

Instead of prefabrication of the antenna and subsequent multistep positioning and bonding processes, this technique uses in-situ polymerization to complete the antenna fabrication and die bonding in a single step after the facile flow focused alignment, condensing the multiple steps of tag fabrication involved in current industrial practice. Moreover, owing to the development of advanced silicon integrated circuit (IC) manufacturing technologies, RFID dies are increasingly produced in smaller size, for example only 100 μm square made by Hitachi, resulting in higher packaging cost because of difficulties in precision handling. [30] Current industrial processes will need new equipments or have to upgrade their existing ones in order to adapt to these smaller silicon dies. The technique we proposed in this manuscript has great potential as it overcomes these limitations through its simple yet precise micro-object handling and arbitrary sheet patterning ability. By simplifying and miniaturizing the tag fabrication processes, this technique would greatly improve current RFID packaging efficiency while significantly reduce the cost of the tags, promoting the massive deployment of RFID tags.

We have developed a slit channel lithography method for polymer sheet patterning and assembly as well as demonstrated its versatility in potential applications. This is the first time that a near centimeter wide PDMS microfluidic channel has been developed and studied for its applications. By taking advantage of the micropatterning ability of photolithography and laminar co-flow property, we showed that this technique can pattern functional polymer sheets bearing geometrical and chemical anisotropy with controllable surface textures in a one-step fashion. With designed patterned features, we were able to readily assemble the hydrogel sheets into different 3D structures for potential application in tissue engineering. In addition, the flow focusing feature of microfluidic channel enabled us to perform single-step connection of RFID dies onto a patterned antenna for RFID tag fabrication. With its versatile while one step polymer sheet synthesis and assembly capability, we believe slit channel lithography will encourage more innovations in a wide range of applications such as membrane-based sensors, organic electronics and sheet structure assembly. Importantly, the continuous processing capacity of flow lithography allows this technique to operate at a high-throughput fashion, which significantly simplifies polymer sheet patterning and assembly processes while improves its efficiency.

Experimental Section

Slit Microfluidic Device Fabrication. Slit PDMS channels up to 8 mm wide was fabricated using soft lithography method. During the fabrication process, a glass plate was placed into the PDMS just above the channel to prevent the channel from sagging.

Photopolymerization Setup. The polymeric sheet synthesis and assembly system are based on a stop flow lithography setup. In a system configuration, a metal arc lamp was used as the UV source (Lumen 200, Prior Scientific, Rockland, Mass., USA) and a UV shutter (Lambda SC, Sutter Instruments, Novato, Calif., USA) was installed in the UV light path to control the UV exposure time. The pneumatic solution feeding system consisted of a serial connection of a pressure regulator (Type 100LR, ControlAir, Amherst, N.H. USA) to a three-way solenoid valve (Model 6014, Burkert, Germany) and at the end, to the PDMS channel. The UV shutter and the solenoid valve were both controlled by a program in Labview (National Instruments, Austin, Tex., USA) through a digital controller (NI 9472, National Instruments, Austin, Tex., USA) to coordinate the synthesis process of flow-stop, UV exposure (synthesis) and flow-resume, in a repeating pace. An inverted microscope Axio Observer (Carl Zeiss, Jena, Germany) equipped with objectives of 5×/0.13, 10×/0.3 and 20×/0.4 (N-Achroplan, Ec plan-Neofluar and korr LD Plan-Neofluar, Carl Zeiss, Jena, Germany) was used for this study. A UV filter set (11000v3, Chroma, VT, USA) was used to filter the UV light source to obtain desired UV excitation for polymerization. The red and green filters (XF101-2, XF100-2 Omegafilters, VT, USA) were used for the fluorescence imaging. The transparency photomasks were designed with AUTOCAD 2011 and printed at a resolution of 25,000 dpi (CAD/Art Services, OR, USA).

Single Layer Sheet Synthesis. In single layer sheet synthesis, channels with depth of 50 μm were used. Geometrically patterned sheets in FIG. 1a-c were synthesized using poly(ethylene glycol) (700) diacrylate (PEG-DA 700, Sigma-Aldrich) with 5% photoinitiator 2-hydroxy-2-methylpropiophenon (Darcour 1173, Sigma-Aldrich) and 0.1% rhodamine B (Sigma-Aldrich) by UV exposure through a 5× objective. The cylindrical pore profile in FIG. 1e was obtained by placing the focal plane in the middle depth of the channel and the conical pore profile in Figure if was produced by lowering the focal plane by 15 μm. The surface textured sheets in FIG. 1g-i were made by varying the components of the prepolymer solution and their concentrations. Smooth (FIG. 1g) and wrinkled surfaces (FIG. 1i) were created using 0% and 60% Ethanol (Sigma-Aldrich) respectively in Poly(ethylene glycol) (575) diacrylate (PEG-DA 575, Sigma-Aldrich) both with 5% Darcour 1173. The porous surface was synthesized using 60% Ethanol and 1% Darcure 1173 in poly(ethylene glycol) (200) diacrylate (PEG-DA 200, Sigma-Aldrich). The fluorescent images were taken by a Nikon D300s camera (Nikon, Canada) and SEM images were obtained through a scanning electron microscopy (FE-SEM S-4500, Hitachi).

Cell-laden sheets and hydrogel sheets assembly. 2-Hydroxy-4′-(2-hydroxyethoxy)-2-methylpropiophenone (Irgacure 2959, Sigma-Aldrich) was used as photoinitiator and dissolved in the mixture of PEG-DA 700 and phosphate buffered saline (PBS). The prepolymer solution without cells was a mixture of 20% (v/v) PEG-DA 700, 3% (w/v) Irgacure 2959, and 80% (v/v) PBS. 3T3 fibroblasts (ATCC, Manassas, Va., USA) containing prepolymer solution was a mixture of 20% (v/v) PEG-DA 700, 3% (w/v) Irgacure 2959, and 80% (v/v) PBS with cell density of 5×106 cells mL-1.

The prepolymer solutions with and without cells were flowed into the channel to form the middle and side streams, respectively. The co-flow streams were polymerized by UV light exposure through a rectangular photomask (FIG. 3a). The sheets were washed by PBS 3 times followed by 30 min. incubation. Then they were stained by live/dead cell viability assay agent (L-3224, Invitrogen, Canada) for 10 min. Both bright field and fluorescent images (FIG. 3b, c) were taken by a Nikon D300s camera.

Elongated hydrogel sheet (FIG. 3d) was produced by polymerizing the sheet with overlapped edges. Rhodamine B was added into the prepolymer solution for fluorescence imaging. The elongated hydrogel sheet was pulled out and rolled onto 1.5 mm diameter glass rod (FIG. 3e). Similar process was used to produce the double-stream elongated sheet, in which Rhodamine B was added into one stream (red) and Fluoresbrite YG carboxylate microspheres solution (1 μm beads, Polysciences Inc., Warrington, Pa., USA) was added to another stream (green). The obtained sheet was then rolled around a 2.1 mm diameter metal tube at certain angle to form a long hydrogel tube. The fluorescent images were taken by a Nikon D300s camera.

To make the magnetic hydrogel, a prepolymer solution containing 10% (v/v) magnetic beads solution (1 μm, Sera-Mag, Thermo Scientific, Canada), 40% (v/v) PEG-DA 700, 50% (v/v) DI water and 6% (w/v) Irgacure 2959 was used as the side streams and non-magnetic prepolymer solution containing 40% (v/v) PEG-DA 700, 60% (v/v) DI water and 5% (w/v) Irgacure 2959 was used as the middle stream (FIG. 3g). 5× objective was used to project the UV light through a pore-arrayed photomask. The fabricated magnetic hydrogel sheets were rinsed and placed in a rectangular PDMS reservoir filled with water (FIG. 3h inset). As the magnetic field was applied and the water was gently agitated by a pipette, the sheets were drawn to the corner and stacked up (FIG. 3h). Images were taken by charge coupled device (CCD) camera (QImaing, Canada).

RFID tag fabrication. RFID dies were obtained from Alien Technology (Morgan Hill, Calif., USA). 2 mg/mL CNT prepolymer solution was obtained by dispersing CNT (Cheaptubes, Brattleboro, Vt., USA) in PEG-DA 700 (40%) and DI water (60%) solution. The die was placed in the middle inlet reservoir. CNT prepolymer solution was passed through the two inlets, forming three streams. The flow rate of the two side streams were controlled at 3 μL s-1 and middle one was controlled at 1 μL s-1. The dies were focused into the middle of the channel and were stopped at a downstream location by pausing the flows (FIG. 4a). An antenna designed photomask was adjusted to align the antenna and the bumps. Then a UV light was projected to the channel through the photomask to polymerize the CNT antenna with the die attached (FIG. 4b), to form a RFID tag. After washing, a stereo microscope (Accu-Scope, Commack, N.Y., USA) was used to observe the tag and images were captured using a Nikon D300s camera (FIG. 4c). The tag was then encapsulated in PEG-DA using prepolymer solution containing 95% PEG-DA 700 and 5% Darcure 1173 and subsequent UV polymerization, making the tag inlay (FIG. 4d).

Slit Microfluidic Device Fabrication. An example embodiment of the slit microfluidic device system 600 is shown in FIG. 6. Polydimethyl-siloxane (PDMS, Sylgard 184, Dow Corning, Midland, Mich., USA) precursor with a mixing ratio of 10:1 (PDMS: curing agent) was used for the fabrication of the slit channel. After partial curing of PDMS on a SU-8 photoresist (Microchem, Newton, Mass., USA) positive relief pattern, a piece of glass slightly wider than the channel was placed on the PDMS surface. Then fresh PDMS precursor was poured onto the surface and subsequently baked at 65° C. for another 2 h, making the slit PDMS channel with glass support inside. The channels were attached to glass slides with partially cured PDMS coating and then baked at 65° C. for another 2 h for bonding. This embodiment of the slit microfluidic device 600 along with its lubrication layer mechanism during UV polymerization is schematically shown in FIG. 6.

Surface Textured Sheets. With reference to FIG. 7, the surface textured sheets 700, due to their different surface morphologies, look different in photographs. Smooth surface sheet is transparent (FIG. 7a), while the porous surface one is opaque (FIG. 7b) and wrinkled one is semitransparent (FIG. 7c).

Cell-laden sheets and hydrogel sheets assembly.

Cellular prepolymer solution preparation. 3T3 fibroblasts (ATCC, Manassas, Va., USA) were grown in Dulbecco's Modified Eagle's medium (DMEM) (Sigma-Aldrich, St. Louis, Mo., USA) supplemented with 10% fetal bovine serum (FBS) and 1% antibiotic. The cells were then incubated at 37° C. in a humidified atmosphere of 95% air and 5% CO2. The cell containing prepolymer solution was a mixture of 20% (v/v) PEG-DA 700, 3% (w/v) Irgacure 2959, and 80% (v/v) PBS with cell density of 5×106 cells mL-1. Before mixing with cells, the prepolymer solution was filter-sterilized through a 0.22 μm filter.

Elongated hydrogel sheet. With reference to FIG. 8, the elongated hydrogel sheet 800 was produced by polymerizing each sheet with overlapped edges. 0.1% (w/v) Rhodamine B was used in the noncellular prepolymer solution for fluorescence imaging. After one UV light projection, the polymerized sheet was moved 2 mm, towards the channel downstream and another UV light was projected. This process was also used to produce the double-stream elongated sheet, in which 0.1% Rhodamine B was added into one stream (red) and 2% Fluoresbrite YG carboxylate microspheres solution (1 μm beads, Polysciences Inc., Warrington, Pa., USA) was added to another stream (green), as shown FIG. 8. The sharp edge implies that multiple chemicals can be incorporated into one hydrogel sheet with controlled lateral distribution.

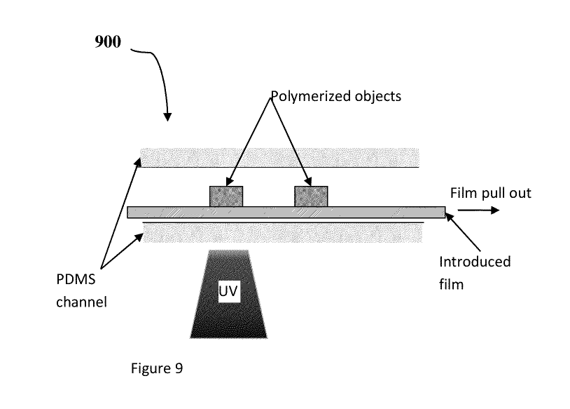

Reference is now made to FIG. 9, which illustrates a system for pull out lithography 900, in accordance with an example embodiment. A transparent film can be introduced in the channel to make patterns on substrate. After UV exposure, the polymerized objects adhere to the film and can be subsequently pulled out of the channel. This system and method can be used for roll-to-roll fabrication of patterns on substrate.

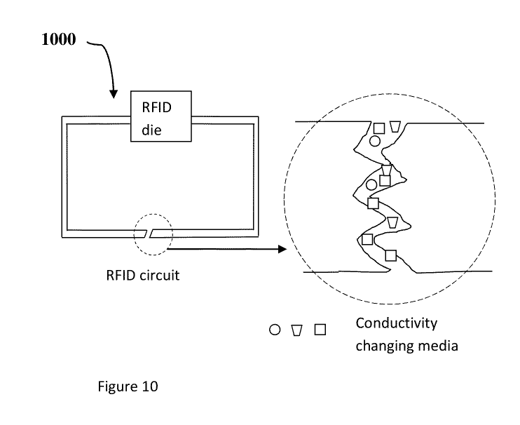

Reference is now made to FIG. 10, which illustrates a patterned circuit 1000 for sensing, in accordance with an example embodiment. Patterned conductive sheets can be used for making sensing circuits and organic electronics. As shown in FIG. 10, a circuit can be patterned with a shaped gap, in which a conductive media (such as conductive microparticles) can alter the conductivity of the circuit through certain means (for example, particle concentration, PH change, particle size, particle location, particle chemical properties). Through detecting the signal received from the circuit, certain physical or chemical quantities related to the conductivity changing media can be measured.

In accordance with some example embodiments which include the channel, in addition to glass, any solid material known by those skilled in the art, such as metal, alloy, plastic and ice, can also be used to support the channel, to prevent it from deformation. In accordance with some example embodiments of the channel, in addition to PDMS, any other suitable materials known by those skilled in the art which can allow the diffusion of oxygen can also be used as the channel material.

In accordance with some example embodiments which include the photomask, the photomask can be any suitable photomask known by those skilled in the art that enables the projection and direction of illumination towards the curable prepolymer.

In accordance with some example embodiments which include the prepolymer materials, photocurable materials including materials can be cured by UV, visible light and IR. In addition to photocurable materials, thermalcurable, PH sensitive materials any other suitable materials known by those skilled in the art, can also be used. In such applications, the source of illumination is a thermal source or other source of radiation.

In accordance with some example embodiments which include the prepolymer materials, the prepolymer stream in the channel comprises a monomer or a monomer stream. The monomer stream can include a biological material such as DNA, RNA, antigen, polypeptide, antibody, enzyme, cells, mitochondria, chromophore, and virus. The monomer stream can include a porogen for making porous sheets. The monomer stream can include particles, such as carbon nanotube, graphene, magnetic particles, quantum dots, electrically conductive particles, glass particles and gas bubbles.

In accordance with some example embodiments, different antibodies can be incorporated into different location in a sheet material for multiplex cell, virus, and biomolecule detection.

In accordance with some example embodiments, CNT/graphene loaded sheets for polymer electrolyte membrane (PEM) in fuel cell, for capacitor in energy storage/battery.

In accordance with some example embodiments, by incorporating magnetic particles into the sheets, 3D laminate structures can be obtained through field assisted self-assembly.

In accordance with some example embodiments, the flow focusing and subsequent in-situ polymerization can also be used for assembling a LED or other micro-component to a planar structure.

While particular embodiments of the invention have been shown and described in detail, it will be obvious to those skilled in the art that changes and modifications of the present invention, in its various embodiments, may be made without departing from the spirit and scope of the invention. Other elements, steps, methods and techniques that are insubstantially different from those described herein are also within the scope of the invention. Thus, the scope of the invention should not be limited by the particular embodiments described herein but should be defined by the appended claims and equivalents thereof.

### REFERENCES

[1] J. A. DeFranco, B. S. Schmidt, M. Lipson, and G. G. Malliaras, “Photolithographic patterning of organic electronic materials,” Organic Electronics, vol. 7, pp. 22-28, 2006.
[2] E. P. Chan, E. J. Smith, R. C. Hayward, and A. J. Crosby, “Surface wrinkles for smart adhesion,” Advanced Materials, vol. 20, pp. 711-716, 2008.
[3] M. Elimelech, X. H. Zhu, A. E. Childress, and S. K. Hong, “Role of membrane surface morphology in colloidal fouling of cellulose acetate and composite aromatic polyamide reverse osmosis membranes,” Journal of Membrane Science, vol. 127, pp. 101-109, 1997.
[4] S. Chung, J. H. Lee, M. W. Moon, J. Han, and R. D. Kamm, “Non-lithographic wrinkle nanochannels for protein preconcentration,” Advanced Materials, vol. 20, pp. 3011-3016, 2008.
[5] W. Lee, C. Y. Bae, S. Kwon, J. Son, J. Kim, Y. Jeong, S. S. Yoo, and J. K. Park, “Cellular Hydrogel Biopaper for Patterned 3D Cell Culture and Modular Tissue Reconstruction,” Advanced Healthcare Materials, vol. 1, pp. 635-639, 2012.
[6] H. B. Wei, B. H. Chueh, H. L. Wu, E. W. Hall, C. W. Li, R. Schirhagl, J. M. Lin, and R. N. Zare, “Particle sorting using a porous membrane in a microfluidic device,” Lab on a Chip, vol. 11, pp. 238-245, 2011.
[7] S. M. Mitrovski, L. C. C. Elliott, and R. G. Nuzzo, “Microfluidic devices for energy conversion: Planar integration and performance of a passive, fully immersed H2-O2 fuel cell,” Langmuir, vol. 20, pp. 6974-6976, 2004.
[8] J. R. Rettig and A. Folch, “Large-scale single-cell trapping and imaging using microwell arrays,” Analytical Chemistry, vol. 77, pp. 5628-5634, 2005.
[9] P. Kim, H. E. Jeong, A. Khademhosseini, and K. Y. Suh, “Fabrication of non-biofouling polyethylene glycol micro- and nanochannels by ultraviolet-assisted irreversible sealing,” Lab on a Chip, vol. 6, pp. 1432-1437, 2006.
[10] Y. Y. Choi, B. G. Chung, D. H. Lee, A. Khademhosseini, J. H. Kim, and S. H. Lee, “Controlled-size embryoid body formation in concave microwell arrays,” Biomaterials, vol. 31, pp. 4296-4303, 2010.
[11] N. W. Choi, M. Cabodi, B. Held, J. P. Gleghorn, L. J. Bonassar, and A. D. Stroock, “Microfluidic scaffolds for tissue engineering,” Nature Materials, vol. 6, pp. 908-915, 2007.
[12] S. Cichos, J. Haberland, and H. Reichl, “Performance analysis of polymer based antenna-coils for RFID,” Polytronic 2002: 2Nd International Ieee Conference on Polymers and Adhesives in Microelectronics and Photonics, Conference Proceedings, pp. 120-124, 2002.
[13] C. Rensch, S. Hell, M. Vonschickfus, and S. Hunklinger, “Laser Scanner for Direct Writing Lithography,” Applied Optics, vol. 28, pp. 3754-3758, 1989.
[14] A. Revzin, R. J. Russell, V. K. Yadavalli, W. G. Koh, C. Deister, D. D. Hile, M. B. Mellott, and M. V. Pishko, “Fabrication of poly(ethylene glycol) hydrogel microstructures using photolithography,” Langmuir, vol. 17, pp. 5440-5447, 2001.
[15] Y. N. Xia and G. M. Whitesides, “Soft lithography,” Annual Review of Materials Science, vol. 28, pp. 153-184, 1998.
[16] L. P. Yeo, S. H. Ng, Z. F. Wang, Z. P. Wang, and N. F. de Rooij, “Micro-fabrication of polymeric devices using hot roller embossing,” Microelectronic Engineering, vol. 86, pp. 933-936, 2009.
[17] T. Haatainen and J. Ahopelto, “Pattern transfer using step&stamp imprint lithography,” Physica Scripta, vol. 67, pp. 357-360, 2003.
[18] D. Dendukuri, P. Panda, R. Haghgooie, J. M. Kim, T. A. Hatton, and P. S. Doyle, “Modeling of Oxygen-Inhibited Free Radical Photopolymerization in a PDMS Microfluidic Device,” Macromolecules, vol. 41, pp. 8547-8556, 2008.
[19] D. Dendukuri, D. C. Pregibon, J. Collins, T. A. Hatton, and P. S. Doyle, “Continuous-flow lithography for high-throughput microparticle synthesis,” Nature Materials, vol. 5, pp. 365-369, 2006.
[20] D. C. Appleyard, S. C. Chapin, and P. S. Doyle, “Multiplexed Protein Quantification with Barcoded Hydrogel Microparticles,” Analytical Chemistry, vol. 83, pp. 193-199, 2011.
[21] S. C. Chapin, D. C. Pregibon, and P. S. Doyle, “High-throughput flow alignment of barcoded hydrogel microparticles,” Lab on a Chip, vol. 9, pp. 3100-3109, 2009.
[22] D. K. Hwang, J. Oakey, M. Toner, J. A. Arthur, K. S. Anseth, S. Lee, A. Zeiger, K. J. Van Vliet, and P. S. Doyle, “Stop-Flow Lithography for the Production of Shape-Evolving Degradable Microgel Particles,” Journal of the American Chemical Society, vol. 131, pp. 4499-4504, 2009.
[23] S. H. Liu, H. A. Becerril, M. C. LeMieux, W. C. M. Wang, J. H. Oh, and Z. N. Bao, “Direct Patterning of Organic-Thin-Film-Transistor Arrays via a “Dry-Taping” Approach,” Advanced Materials, vol. 21, pp. 1266-+, 2009.
[24] S. Selimovic, F. Piraino, H. Bae, M. Rasponi, A. Redaelli, and A. Khademhosseini, “Microfabricated polyester conical microwells for cell culture applications,” Lab on a Chip, vol. 11, pp. 2325-2332, 2011.
[25] J. R. Bostwick and W. D. Le, “A Tyrosine-Hydroxylase Assay in Microwells Using Coupled Nonenzymatic Decarboxylation of Dopa,” Analytical Biochemistry, vol. 192, pp. 125-130, 1991.
[26] E. P. Chan, K. A. Page, S. H. Im, D. L. Patton, R. Huang, and C. M. Stafford, “Viscoelastic properties of confined polymer films measured via thermal wrinkling,” Soft Matter, vol. 5, pp. 4638-4641, 2009.
[27] H. S. Kim and A. J. Crosby, “Solvent-Responsive Surface via Wrinkling Instability,” Advanced Materials, vol. 23, pp. 4188-4192, 2011.
[28] L. G. Griffith and G. Naughton, “Tissue engineering—Current challenges and expanding opportunities,” Science, vol. 295, pp. 1009-+, 2002.
[29] N. E. Fedorovich, J. Alblas, J. R. de Wijn, W. E. Hennink, A. J. Verbout, and W. J. A. Dhert, “Hydrogels as extracellular matrices for skeletal tissue engineering: state-of-the-art and novel application in organ printing,” Tissue Engineering, vol. 13, pp. 1905-1925, 2007.
[30] S. Preradovic and N. C. Karmakar, “Low Cost Chipless RFID Systems,” in Multiresonator-Based Chipless RFID. New York, USA: Springer US, 2012.
[31] J. S. Smith, “Fluidic self-assembly of active antenna,” US Patent, vol. U.S. Pat. No. 6,661,237, 2003.
[32] A. Mehdipour, I. D. Rosca, A. R. Sebak, C. Trueman, and S. V. Hoa, “Carbon Nanotube Composites for Wideband Millimeter-Wave Antenna Applications,” Ieee Transactions on Antennas and Propagation, vol. 59, pp. 3572-3578, 2011.
[33] X. Y. Zeng, Q. K. Zhang, R. M. Yu, and C. Z. Lu, “A New Transparent Conductor: Silver Nanowire Film Buried at the Surface of a Transparent Polymer,” Advanced Materials, vol. 22, pp. 4484-4488, 2010.
[34] R. Abargues, P. J. Rodriguez-Canto, R. Garcia-Calzada, and J. Martinez-Pastor, “Patterning of Conducting Polymers Using UV Lithography: The in-Situ Polymerization Approach,” Journal of Physical Chemistry C, vol. 116, pp. 17547-17553, 2012.

What is claimed is:

1. A method for synthesizing polymeric sheets, comprising:
providing a substrate which defines a slit channel having a plane's width of at least 1 mm;
providing a solid layer at the slit channel to prevent the slit channel from sagging;
flowing a curable prepolymer responsive to illumination through the slit channel;
pausing the flow of the curable prepolymer responsive to illumination; and
projecting a source pulse of illumination to the slit channel through a photomask to the paused flow of the curable prepolymer responsive to illumination, to produce a polymeric sheet.

2. The method of claim 1, wherein the slit channel has an aspect ratio of width to height of at least 100:1.

3. The method of claim 1, further comprising resuming flow and flushing the polymeric sheet.

4. The method of claim 1, wherein the photomask includes a specified design.

5. The method of claim 4, wherein the specified design includes at least one of micropores and geometrical patterns.

6. The method of claim 1, further comprising applying the method to one of a lab-on-a-chip, an RFID circuit, tissue engineering, organic electronics, and to generate a filtration membrane.

7. The method of claim 1, further comprising repeating the flowing, the pausing and the projecting to a stream of the curable prepolymer.

8. The method of claim 7, further comprising overlapping a trailing edge of a synthesized first polymeric sheet onto a leading edge of a subsequently synthesized second polymeric sheet to produce an elongated polymeric sheet formed from the overlapped first and second polymeric sheets.

9. The method of claim 1, further carrying a micro-object using the curable prepolymer responsive to illumination through the channel; and
pausing the flow of the curable prepolymer responsive to illumination when the micro-object is aligned with the photomask.

10. The method of claim 9 wherein the curable prepolymer is an electrically conductive prepolymer solution, the micro-object is a die and the photomask is designed in an antenna pattern, and wherein the projecting the source pulse of illumination to the slit channel through the photomask forms an antenna and bonds the die to the antenna forming an electrical circuit.

11. The method of claim 1, wherein the substrate is defined by a layer including Polydimethylsiloxane (PDMS).

12. The method of claim 1, wherein the slit channel is supported by the solid layer, the solid layer including at least one of glass, metal, alloy, plastic and ice.

13. The method of claim 12 wherein the solid layer is dimensioned slightly larger than the slit channel.

14. The method of claim 1, wherein the slit channel is defined by a layer of a suitable material which allows diffusion of oxygen.

15. The method of claim 1, wherein the plane's width is about 8 mm.

16. The method of claim 1, wherein the curable prepolymer includes a photocurable prepolymer that can be cured by ultraviolet (UV), visible light or infrared (IR), or a thermalcurable prepolymer.

17. The method of claim 1, wherein the curable prepolymer in the slit channel comprises a monomer.

18. The method of claim 17, wherein the monomer includes a biological material including at least one of a DNA, RNA, antigen, polypeptide, antibody, enzyme, cells, mitochondria, chromophore, and virus, or a porogen for making porous sheets.

19. The method of claim 17 wherein the monomer includes a water soluble solution.

20. The method of claim 17, wherein the monomer includes particles, including at least one of carbon nanotube, graphene, magnetic particles, quantum dots, electrically conductive particles, glass particles and gas bubbles.

21. The method of claim 1, wherein different antibodies are incorporated into different location in a sheet material for at least one of multiplex cell, virus, and biomolecule detection.

22. The method of claim 1, wherein patterned conductive sheets are synthesized for at least one of sensing circuits and organic electronics.

23. The method of claim 1, wherein carbon nanotube (CNT) or graphene loaded sheets are synthesized for polymer electrolyte membrane (PEM) in a fuel cell, or for a capacitor in energy storage or battery.

24. The method of claim 1, further comprising incorporating magnetic particles into the polymeric sheet.

25. The method of claim 1, wherein flow focusing and subsequent in-situ polymerization can also be used for assembling a LED or other micro-component to a planar structure.

26. The method of claim 1 further comprising adjusting the focal plane to different vertical positions of the slit channel to form cylindrical or conical pore profiles.

27. The method of claim 1 wherein the polymeric sheets have a width of at least 1 mm.

28. A method for synthesizing a polymeric sheet including membranes, comprising:
providing a substrate defining a slit channel;
providing a solid layer at the slit channel to prevent the slit channel from sagging;
flowing a curable prepolymer responsive to illumination through the slit channel;
pausing the flow of curable prepolymer responsive to illumination; and
projecting a source pulse of illumination to the slit channel through a photomask to the paused flow of curable prepolymer responsive to illumination, to produce the polymeric sheet including membranes.

29. A method for synthesizing a radio frequency identification tag, comprising:
providing a substrate defining a slit channel,
providing a solid layer at the slit channel to prevent the slit channel from sagging,
flowing an electrically conductive curable prepolymer through the slit channel,
carrying a die using the electrically conductive curable prepolymer responsive to illumination through the slit channel,
pausing the flow of the electrically conductive curable prepolymer responsive to illumination when the die is aligned with the photomask designed in an antenna pattern,
and projecting a source pulse of illumination to the slit channel through the photomask to the paused flow of the electrically conductive curable prepolymer to form an antenna and to bond the die to the antenna, to produce the radio frequency identification tag.

30. The method of claim 29 further comprising:
positioning the die in the slit channel by flowing a stream of the electrically conductive curable prepolymer into the slit channel along each side of the die.

31. The method of claim 29 wherein the slit channel is dimensioned to align the die with the photomask.

32. The method of claim 29 further comprising:
positioning the die carried by the electrically conductive curable prepolymer in the slit channel using a magnetic force.

33. A system for synthesizing a polymeric sheet, comprising:
a substrate defining a slit channel having a plane's width of at least 1 mm;
a solid layer at the slit channel to prevent the channel from sagging;
a control configured for controlling flow of a curable prepolymer to be flowing or paused, the curable prepolymer responsive to illumination;
a photomask; and
a source pulse of illumination to the slit channel projected to the channel through the photomask to the paused flow of curable prepolymer, to produce the polymeric sheet.

34. The system of claim 33 wherein the slit channel has an aspect ratio of width to height of at least 100:1.

35. The system of claim 33 where the solid layer includes at least one of glass, metal, alloy, plastic and ice.
